(19) United States
(12) Patent Application Publication
(10) Pub. No.: US 2013/0000958 A1
(43) Pub. Date: Jan. 3, 2013

(54) MULTILAYER CERAMIC SUBSTRATE AND METHOD FOR MANUFACTURING THE SAME

(75) Inventors: Yong Seok CHOI, Gyeonggi-do (KR); Dae Hyeong Lee, Seoul (KR); Won Chul Ma, Gyeonggi-do (KR); Ki Pyo Hong, Gyeonggi-do (KR)

(73) Assignee: SAMSUNG ELECTRO-MECHANCIS CO., LTD.

(21) Appl. No.: 13/473,047

(22) Filed: May 16, 2012

(30) Foreign Application Priority Data
Jun. 30, 2011 (KR) 10-2011-0065187

(51) Int. Cl. H05K 1/03; B05D 5/12; B82Y 40/00; B82Y 30/00

(52) U.S. Cl. 174/255; 427/98.3; 977/892; 977/773; 977/775

(57) ABSTRACT

Disclosed herein are a multilayer ceramic substrate and a method for manufacturing the same. In a method for manufacturing the multilayer ceramic substrate, which has a ceramic laminate including multiple ceramic layers and allowing interconnection between layers through vias respectively formed in the multiple ceramic layers, the method includes: preparing a ceramic laminate in which a void is formed around a via in at least one ceramic layer of multiple ceramic layers; immersing the ceramic laminate in a precipitating bath in which an electrode solution is contained; putting the ceramic laminate out of the precipitating bath after a predetermined period of time, and then removing a nanoparticle film stacked on a surface of a multilayer ceramic substrate; and applying heat to the multilayer ceramic substrate to form nanoparticles filling an inside of the void, after the removing of the nanoparticle film.

### CROSS REFERENCE(S) TO RELATED APPLICATIONS

This application claims the benefit under 35 U.S.C. Section 119 of Korean Patent Application Serial No. 10-2011-0065187, entitled “Multilayer Ceramic Substrate and Method for Manufacturing the Same” filed on Jun. 30, 2011, which is hereby incorporated by reference in its entirety into this application.

### BACKGROUND OF THE INVENTION

1. Technical Field

The present invention relates to a multilayer ceramic substrate and a method for manufacturing the same, and more particularly, to a multilayer ceramic substrate for repairing a void around a via and a method for manufacturing the same.

2. Description of the Related Art

In recent, as miniaturization of electronic parts intensifies and continues, small-sized modules and substrates have been developed by precision-making, fine-patterning, and thinning the electronic parts. However, when a normally used printed circuit board (PCB) is applied in the small-sized electronic part, there occur disadvantages, such as size reduction, signal loss at a high frequency region, and deterioration in reliability at high temperature and high humidity.

A substrate using ceramics instead of the PCB is used in order to overcome these disadvantages. A main component of a multilayer ceramic substrate is a ceramic composition allowing low-temperature co-firing and containing a large amount of glass.

A low temperature co-fired ceramic (LTCC) substrate may be manufactured by various methods, which are divided into a shrinkage process and a non-shrinkage process according to whether or not the multilayer ceramic substrate shrinks at the time of firing.

Specifically, the multilayer ceramic substrate is shrunken and manufactured at the time of firing according to the shrinkage process. However, in the shrinkage process, a shrinking degree of the multilayer ceramic substrate is not uniform throughout the multilayer ceramic substrate, and thus, a dimension change occurs in a surface direction of the substrate. This shrinkage in the surface direction of the multilayer ceramic substrate causes printed circuit patterns included in the substrate to be deformed, thereby deteriorating precision of pattern position and causing short circuits in the patterns.

The non-shrinkage process for preventing the shrinkage in the surface direction of the multilayer ceramic substrate at the time of firing is being proposed, in order to solve the problems caused by the shrinkage process.

According to the non-shrinkage process, restriction layers are formed on both surfaces of the multilayer ceramic substrate at the time of firing. In this case, a material, which is not shrunken at a temperature at which the multilayer ceramic substrate is fired and easily shrinkage-controlled, may be used for the restriction layer. The multilayer ceramic substrate is not shrunken in the surface direction thereof by the restriction layer, but can be shrunken only in a thickness direction thereof.

As such, when the multilayer ceramic substrate is manufactured by applying this non-shrinkage process, the shrinkage in the surface direction of the substrate can be suppressed at the time of firing. However, a via vertically formed for interlayer connection does not correspond to firing characteristics of a normal low temperature co-fired ceramic (LTCC) and has difficulty in giving a restriction force for suppressing the shrinkage in the surface direction, and thus, voids are generated.

In particular, when the voids around the via are exposed to a surface layer, and this causes external patterns to be defective. In other words, the voids around the via appear in various types, such as a void, a crack, a protrusion, a depression, and the like, which causes defects in packaging, such as wire bonding, SMT, soldering, or the like, and deterioration in reliability.

### SUMMARY OF THE INVENTION

An object of the present invention is to provide a member for preventing a binding strength between an external electrode and a ceramic laminate from being lowered, by filling a void around a via of the ceramic laminate with nanoparticles.

According to an exemplary embodiment of the present invention, there is provided a method for manufacturing a multilayer ceramic substrate, which has a ceramic laminate including multiple ceramic layers and allowing interconnection between layers through vias respectively formed in the multiple ceramic layers, the method including: preparing a ceramic laminate in which a void is formed around a via in at least one ceramic layer of multiple ceramic layers; immersing the ceramic laminate in a precipitating bath in which an electrode solution is contained; putting the ceramic laminate out of the precipitating bath after a predetermined period of time, and then removing a nanoparticle film stacked on a surface of a multilayer ceramic substrate; and applying heat to the multilayer ceramic substrate to form nanoparticles filling an inside of the void, after the removing of the nanoparticle film.

According to an exemplary embodiment of the present invention, there also is provided a method for manufacturing a multilayer ceramic substrate, which has a ceramic laminate including a deep ceramic layer and a superficial ceramic layer and allowing interconnection between layers through vias respectively formed in the multiple ceramic layers, the method including: preparing a ceramic laminate in which a void is formed around a via in at least one ceramic layer of the deep ceramic layer and the superficial ceramic layer; placing the ceramic laminate on a bottom surface in an empty precipitating bath, and then pouring an electrode solution into the precipitating bath; putting the ceramic laminate out of the precipitating bath after a predetermined period of time, and then removing a nanoparticle film stacked on a surface of a multilayer ceramic substrate; and applying heat to the multilayer ceramic substrate to form nanoparticles filling an inside of the void, after the removing of the nanoparticle film.

According to an exemplary embodiment of the present invention, there also is provided a multilayer ceramic substrate, which has a ceramic laminate including multiple ceramic layers and allowing interconnection between layers through vias respectively formed in the multiple ceramic layers, the multilayer ceramic substrate including: a ceramic laminate having a void formed around a via in at least one ceramic layer of the multiple ceramic layers; an external electrode formed on the ceramic laminate; and nanoparticles filing the void to electrically connect the ceramic laminate and the external electrode.

### BRIEF DESCRIPTION OF THE DRAWINGS

FIG. 1 is a cross-sectional view of a multilayer ceramic substrate according to an exemplary embodiment of the present invention; and

FIGS. 2A to 2E are cross-sectional views showing a method for manufacturing a multilayer ceramic substrate according to an exemplary embodiment.

### DESCRIPTION OF THE PREFERRED EMBODIMENTS

Hereinafter, exemplary embodiments of the present invention will be described with reference to the accompanying drawings. However, the exemplary embodiments are described by way of examples only and the present invention is not limited thereto.

Further, when it is determined that the detailed description of the known art related to the present invention may obscure the gist of the present invention, the detailed description thereof will be omitted. Further, the following terminologies are defined in consideration of the functions in the present invention and may be construed in different ways by the intention or customs of the users and operators. Therefore, the definitions thereof should be construed based on the contents throughout the specification.

The technical idea of the present invention is determined by the claims and the exemplary embodiments herein are provided so that the technical idea of the present invention will be efficiently explained to those skilled in the art to which the present invention pertains.

Hereinafter, a multilayer ceramic substrate according to exemplary embodiments of the present invention will be described with reference to the accompanying drawings.

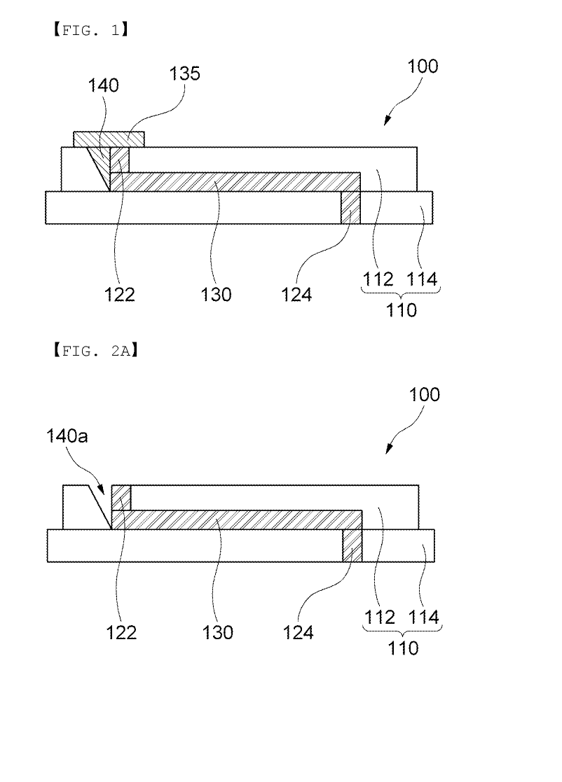

FIG. 1 is a cross-sectional view of a multilayer ceramic substrate according to an exemplary embodiment of the present invention.

As shown in FIG. 1, a multilayer ceramic substrate 100 according to an exemplary embodiment of the present invention may include a ceramic laminate 110 and an external electrode 135.

The ceramic laminate 110 may include multilayer-laminated ceramic layers 112 and 114. Here, the multilayer-laminated ceramic layers 112 and 114 may have first and second vias 122 and 124, respectively, which include a conductive material filling via holes (not shown) pas sing through a body, for example, a silver (Ag) material. The respective ceramic layers 112 and 114 are electrically connected by the first and second vias 122 and 124.

Meanwhile, the first via 122 fills a via hole, which is formed to pass through a superficial ceramic layer 112 of the multilayer-laminated ceramic layers 112 and 114, on the drawing, and the second via 124 fills a via hole, which is formed to pass through a deep ceramic layer 114 of the multilayer-laminated ceramic layers 112 and 114, on the drawing.

An inner electrode 130 is further provided between the laminated ceramic layers 112 and 114, and electrically connected to the first and second vias 112 and 124.

The first and second vias 122 and 124, which vertically passes through the ceramic layers 112 and 114, respectively, may be formed by forming via holes in the respective ceramic layers 112 and 114 at appropriate positions in a punching type, depending on circuits of a module, and then filling the via holes with a conductive material, such as silver (Ag) or the like.

In particular, a hole type void (not shown) is formed inside the superficial ceramic layer 112, of the multiple ceramic layers 112 and 114 constituting the ceramic laminate 110 of the multilayer ceramic substrate 100 according to an exemplary embodiment of the present invention, to expose one surface of the first via 122.

Here, the void (not shown) is not formed at random. The void is formed since positions of patterns included in the multilayer ceramic substrate are changed due to shrinkage in a surface direction of the multilayer ceramic substrate, in manufacturing the multilayer ceramic substrate.

Therefore, according to the present invention, the void (not shown) is filled with nanoparticles 140 to be repaired, and thus, can be electrically connected to the via 122. For example, the nanoparticles 140 according to the exemplary embodiment of the present invention may be made of a conductive material having a nanoparticle, such as nano silver (Ag), nano ceramic, or the like.

Meanwhile, the external electrode 135 is electrically connected to the nanoparticles 140 and the via 122.

As such, in the multilayer ceramic substrate 100 according to the exemplary embodiment of the present invention described above, the void around the first via 122 is generated in a type of a void, a crack, a protrusion, or a depression, due to shrinkage difference between the ceramic layers 112 and 114 and the vias 122 and 124, at the time when the ceramic laminate 110 obtained by laminating the inner electrode 130 and multiple ceramic layers 112 and 114 having the first and second vias 122 and 124 is low-temperature co-fired. Here, the void is filled with nanoparticles 140, and thus, can be repaired.

As such, in the multilayer ceramic substrate 100 according to the exemplary embodiment of the present invention, a binding strength between an external electrode 135 and a ceramic laminate 110 can be prevented from being lowered, by filling the voids around the via 122 of the ceramic laminate 110 with nanoparticles 140, and forming the external electrode 135 on the nanoparticles 140 and a surface of the via 122.

Therefore, according to the exemplary embodiment of the present invention, electric reliability can be improved in a process of forming an external electrode 135 on the ceramic laminate 110 and a subsequent packaging process, such as SMT, wire bonding, soldering, and the like.

In the exemplary embodiment of the present invention, the ceramic laminate 110 is drawn and described as having the two ceramic layers 112 and 114 stacked, but this is not limited thereto since the two ceramic layers are drawn only for convenience of explanation.

In addition, in the exemplary embodiment of the present invention, the void is drawn and described as being formed only around the first via 122 formed in the superficial ceramic layer 112, for convenience of explanation, but not limited thereto. For example, void or voids may be formed to expose both lateral surfaces of the first via 122, or formed to expose one lateral surface or both lateral surfaces of the second via 124 formed in the deep ceramic layer 114.

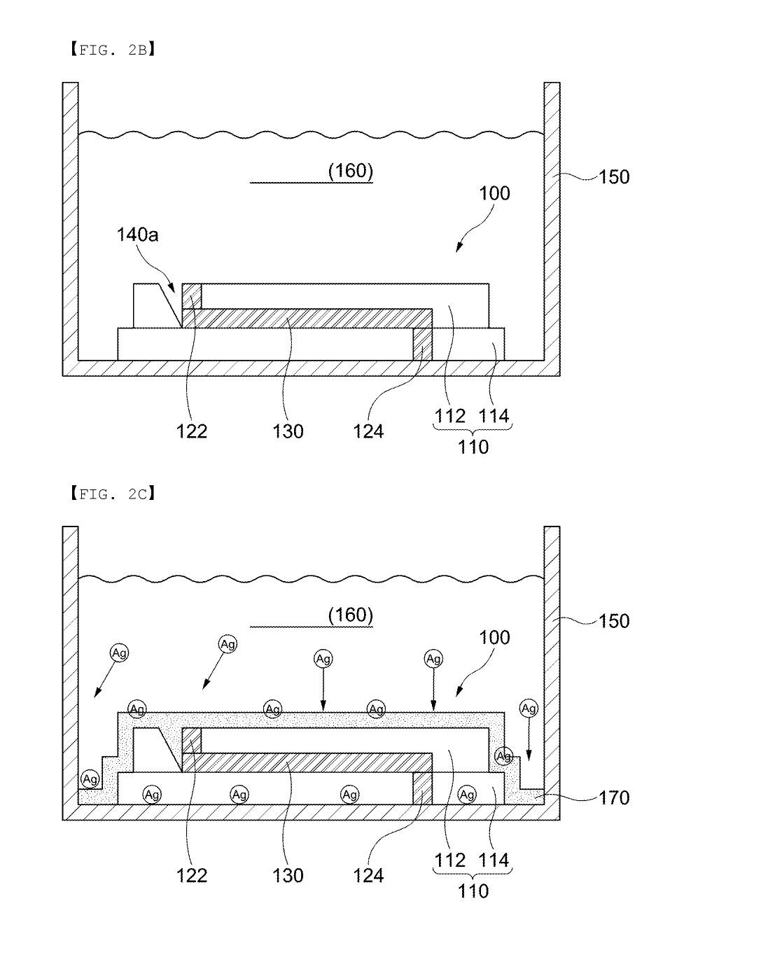

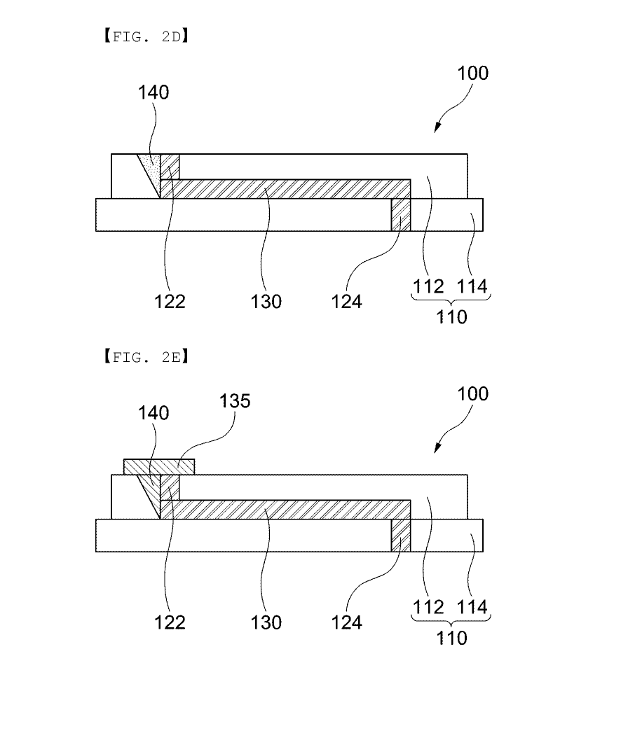

FIGS. 2A to 2E are cross-sectional views showing a method for manufacturing a multilayer ceramic substrate according to an exemplary embodiment.

First, as shown in FIG. 2A, a multilayer ceramic substrate 100, where a void 140a around a via 122 is formed, is prepared.

Here, the multilayer ceramic substrate 100 of the present invention may consist of a ceramic laminate 110 including multilayer-laminated ceramic layers 112 and 114. Although not shown in the drawing, restriction sheets (not shown) are laminated on upper and lower surfaces of the ceramic laminate 110, and the restriction sheets may be fired at a temperature higher than a firing temperature of the ceramic layers 112 and 114, for example, 1500° C. or higher. Here, an alumina (Al₂O₃) sheet or the like may be used as the restriction sheet (not shown).

Here, first and second vias 122 and 124 may be formed in the multilayer-laminated ceramic layers 112 and 114, respectively, and the first and second vias 122 and 124 include a conductive material filling the via holes (not shown) passing through a body, for example, a silver (Ag) material.

In addition, an inner electrode 130 is further provided between the laminated ceramic layers 112 and 114, and electrically connected to the first and second vias 122 and 124. Here, the inner electrode 130 may be formed by using a conductive material such as silver (Ag) in a screen printing type or the like.

Meanwhile, the void 140a in the present invention is generated in a type of void, crack, protrusion, or depression, due to shrinkage difference between the ceramic layers 112 and 114 and the vias 122 and 124, at the time when the ceramic laminate 110, which is obtained by laminating the inner electrode 130 and multiple ceramic layers 112 and 114 having the first and second vias 122 and 124, is low-temperature co-fired.

Here, in the present invention, the void 140a is drawn and described as being formed only around the first via 122 formed in the superficial ceramic layer 112, for convenience of explanation, but not limited thereto. For example, void or voids may be formed to expose both lateral surfaces of the first via 122, or formed to expose one lateral surface or both lateral surfaces of the first via 122, and the second via 124 formed in the deep ceramic layer 114.

Referring to FIG. 2B, the ceramic laminate 110 having the void 140a is immersed in a precipitating bath 150, which is filled with an electrode solution 160.

Here, the electrode solution 160 is a solution where a nanopowder is mixed with water (H₂O) or an organic solvent (hereinafter, referred to as ethanol) solution, and the agglomerated nanopowder is uniformly dispersed by ball milling or ultrasonic dispersion.

Here, the nanopowder in the present invention may be, for example, a conductive material, such as silver (Ag) or ceramic, having nano-level particles.

Meanwhile, in the present invention, a case where the ceramic laminate 110 having the void 140a is immersed in the precipitating bath 150 filled with an electrode solution 160, is drawn and described, but is not limited thereto. For example, as an alternative method, the ceramic laminate 110 having the void 140a is put inside an empty precipitating bath 150, that is to say, nothing is there, and then the electrode solution 160 is poured into the precipitating bath 150.

Referring to FIG. 2C, a nanoparticle film 170 is formed to cover the entire front surface and the void 140a of the ceramic laminate 110.

More specifically, when the ceramic laminate 110 having the void 140a is immersed in the precipitating bath 150 in which the dispersed electrode solution 160 is contained, the nanopowder sinks onto a surface of the ceramic laminate 110 and a bottom surface of the precipitating bath due to gravity. As a result, the void 140a of the ceramic laminate 110 can be filled and a nanoparticle film 170 covering the entire surface may be formed.

Meanwhile, in the drawing of the present invention, a silver (Ag) nano powder is drawn as an example, but not limited thereto. For example, a ceramic nano powder is substituted therefore.

Referring to FIG. 2D, the nanoparticle film 170 formed on the surface of the ceramic laminate 110 is removed, thereby manufacturing the multilayer ceramic substrate 100 having nanoparticles 140.

More specifically, the ceramic laminate 110 having the void 140a is immersed in the precipitating bath 150 in which the dispersed electrode solution 160 is contained, and then, after the passage of a predetermined period of time, the ceramic laminate 110 having the nanoparticle film 170 is put out from the precipitating bath 150.

Then, the nanoparticle film 170 is scraped out by using a squeeze or a paddle, and thus, it can be removed from the surface of the ceramic laminate 110. Here, since the squeeze or paddle is moved in a direction parallel with the ceramic laminate 110, the nanoparticles 140 embedded inside the void 140a is not removed.

Meanwhile, in the present invention, the passage of the predetermined period of time, for example, means a time period while an inside of the void 140a is entirely filled with the nanopowder.

Referring to FIG. 2E, firing is performed by application of heat, thereby preventing the nanoparticles 140 from getting out of the void 140a. Here, the heat may be applied at a temperature of 300 to 400° C.

Then, an external electrode 135 is formed on the ceramic laminate 110 in which the nanoparticles 140 and the first via 122 are formed, thereby preventing the reliability of the substrate from being deteriorated due to the void around the first via 122. Here, the external electrode 135 may be formed of, for example, a conductive material, such as silver (Ag), like the inner electrode 130.

Therefore, according to the exemplary embodiment of the present invention, an electric connection can be favorably performed in a process of forming an external electrode 135 on the ceramic laminate 110 and a subsequent packaging process, such as SMT, wire bonding, soldering, and the like. Therefore, the present invention can improve the reliability of the non-shrinkage multilayer ceramic substrate and lower the fraction defective.

As set forth above, the present invention can prevent a binding strength between an external electrode and a ceramic laminate from being lowered, by filling a void around a via of the ceramic laminate with nanoparticles and forming the external electrode on the nanoparticles and a surface of the via.

In addition, the present invention can improve electric reliability in a process of forming the external electrode on the ceramic laminate and a subsequent packaging process, such as SMT, wire bonding, soldering, and the like.

While the present invention has been shown and described in connection with the embodiments, it will be apparent to those skilled in the art that modifications and variations can be made without departing from the spirit and scope of the invention as defined by the appended claims.

What is claimed is:

1. A method for manufacturing a multilayer ceramic substrate, which has a ceramic laminate including multiple ceramic layers and allowing interconnection between layers through vias respectively formed in the multiple ceramic layers, the method comprising:
preparing a ceramic laminate in which a void is formed around a via in at least one ceramic layer of multiple ceramic layers;
immersing the ceramic laminate in a precipitating bath in which an electrode solution is contained;
putting the ceramic laminate out of the precipitating bath after a predetermined period of time, and then removing a nanoparticle film stacked on a surface of a multilayer ceramic substrate; and
applying heat to the multilayer ceramic substrate to form nanoparticles filling an inside of the void, after the removing of the nanoparticle film.

2. The method according to claim 1, further comprising forming the nanoparticle film by allowing a nanopowder of the electrode solution to be stacked onto the inside of the void, a surface of the multilayer ceramic substrate, and a bottom surface of the precipitating bath, due to gravity, between the immersing of the ceramic laminate and the removing of the nanoparticle film.

3. The method according to claim 2, wherein the electrode solution is prepared by mixing the nanopowder with water, and then dispersing the nanopowder.

4. The method according to claim 2, wherein the electrode solution is prepared by mixing the nanopowder with organic solvent, and then dispersing the nanopowder.

5. The method according to claim 2, wherein the nanopowder is a nano-level silver (Ag) or ceramic particle.

6. The method according to claim 3 or 4, the nanopowder is dispersed through ball milling or ultrasonic dispersion.

7. The method according to claim 1, wherein the predetermined period of time corresponds to a time period while the inside of the void is filled with the nanopowder.

8. A method for manufacturing a multilayer ceramic substrate, which has a ceramic laminate including a deep ceramic layer and a superficial ceramic layer and allowing interconnection between layers through vias respectively formed in the multiple ceramic layers, the method comprising:
preparing a ceramic laminate in which a void is formed around a via in at least one ceramic layer of the deep ceramic layer and the superficial ceramic layer;
placing the ceramic laminate on a bottom surface in an empty precipitating bath, and then pouring an electrode solution into the precipitating bath;
putting the ceramic laminate out of the precipitating bath after a predetermined period of time, and then removing a nanoparticle film stacked on a surface of a multilayer ceramic substrate; and
applying heat to the multilayer ceramic substrate to form nanoparticles filling an inside of the void, after the removing of the nanoparticle film.

9. A multilayer ceramic substrate, which has a ceramic laminate including multiple ceramic layers and allowing interconnection between layers through vias respectively formed in the multiple ceramic layers, the multilayer ceramic substrate comprising:
a ceramic laminate having a void formed around a via in at least one ceramic layer of the multiple ceramic layers;
an external electrode formed on the ceramic laminate; and
nanoparticles filing the void to electrically connect the ceramic laminate and the external electrode.
